(19) United States
(12) Patent Application Publication
(10) Pub. No.: US 2009/0253078 A1
(43) Pub. Date: Oct. 8, 2009

(54) DOUBLE EXPOSURE LITHOGRAPHY USING LOW TEMPERATURE OXIDE AND UV CURE PROCESS

(75) Inventors: Nikolaos Bekiaris, Santa Clara, CA (US); Junyan Dai, Santa Clara, CA (US); Hiram Cervera, San Jose, CA (US); Hali Janine Lana Forstner, Belmont, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Sokudo Co., Ltd., Kyoto (JP)

(21) Appl. No.: 12/415,690

(22) Filed: Mar. 31, 2009

Related U.S. Application Data
(60) Provisional application No. 61/043,022, filed on Apr. 7, 2008.

(51) Int. Cl. G03F 7/20; G03B 27/62

(52) U.S. Cl. 430/312; 430/324; 430/325; 355/75

(57) ABSTRACT

A method of processing a substrate includes forming a first layer having a photosensitive response to incident radiation on the substrate, forming a first pattern in the first layer, and exposing the first pattern to ultra-violet radiation. The exposure of the first pattern to ultra-violet radiation increases the resistance of the first pattern to a developer. The method also includes forming a conformal protective layer over the first pattern and at least a portion of the substrate. The method further includes forming a second layer having a photosensitive response to incident radiation over the conformal protective layer and forming a second pattern in the second layer.

### CROSS-REFERENCES TO RELATED APPLICATIONS

This present application claims priority to U.S. Provisional Patent Application No. 61/043,022, filed on Apr. 7, 2008, the disclosure of which is hereby incorporated by reference in its entirety for all purposes.

### BACKGROUND OF THE INVENTION

The present invention relates generally to the field of semiconductor processing equipment. In particular, embodiments of the present invention are related to lithographic systems utilized during semiconductor processing operations. More particularly, the present invention relates to a method and apparatus for performing double exposure lithography inside a semiconductor processing chamber, however, it would be recognized that the invention has a much broader range of applicability.

Since the invention of the integrated circuit (IC), semiconductor chip features have become exponentially smaller and the number of transistors per device exponentially larger. Advanced IC's with hundreds of millions of transistors at feature sizes of 0.18 μm and less are becoming routine. Improvement in overlay tolerances in optical photolithography and the introduction of new light sources with progressively shorter wavelengths, have allowed optical steppers to significantly reduce the resolution limit for semiconductor fabrication to keep pace with the feature size shrinkage. To continue to make chip features smaller, and increase the transistor density of semiconductor devices, IC's that have features smaller than the lithographic wavelength are being fabricated. For example, this can include fabrication of smaller width and spacing for: interconnecting lines, diameter of contact holes, surface geometry, such as corners and edges, and the like. Accordingly, reducing the dimensions between such small features (critical dimensions (CDs)) can facilitate achieving higher device densities. The lithography process is an important facet of improving packaging density and precision in a semiconductor structure.

Typically, lithography is a process in semiconductor fabrication that relates to the transfer of patterns between media. More specifically, lithography can refer to transfer of patterns onto a thin film that has been deposited onto a substrate or semiconductor wafer. The transferred patterns can then act as a blueprint for desired circuit components. For example, various patterns can be transferred to a photoresist (e.g., radiation-sensitive film), which is the thin film that overlies the substrate during an imaging process described as “exposure” of the photoresist layer. During exposure, the photoresist is subjected to an illumination source (e.g. UV-light, electron beam, X-ray, or the like), which passes through a pattern template, or reticle, to print the desired pattern in the photoresist. Upon exposure to the illumination source, radiation-sensitive qualities of the photoresist permit a chemical transformation in exposed areas of the photoresist, which in turn alters the solubility of the photoresist in exposed areas relative to that of unexposed areas. When a particular solvent developer is applied, exposed areas of the photoresist are dissolved and removed, resulting in a three-dimensional pattern in the photoresist layer. This pattern is at least a portion of the semiconductor device that contributes to final function and structure of the device, or wafer.

The semiconductor processing industry is currently pursuing several different methods in the ongoing effort to shrink device features and increase device density. Several techniques, collectively termed as Next Generation Lithography (NGL), are under investigation. However, none of these techniques are currently commercially viable. Hence, there is a need in the industry for techniques and systems that can extend the life of current lithography tools and processes and at the same time accommodate the shrinking of the device features.

### SUMMARY OF THE INVENTION

According to embodiments of the present invention, techniques related to the field of substrate processing are provided. In particular, embodiments of the present invention are related to lithographic systems utilized during semiconductor processing operations. More particularly, the present invention relates to a method and apparatus for performing double exposure lithography inside a semiconductor processing chamber, however, it would be recognized that the invention has a much broader range of applicability.

In a specific embodiment of the present invention, an apparatus for performing a double exposure lithography process is provided. The apparatus includes several different modules for performing the various steps of a lithographic processes like forming a photosensitive layer on a substrate, developing the photosensitive layer, thermal treatment of the photosensitive layer, and the like. More specifically, the apparatus includes a cure module that is configured to expose the substrate to ultra-violet radiation and a deposition module that is configured to perform Atomic Layer Deposition (ALD).

According to another embodiment of the present invention, a method of processing a substrate is provided. The method includes forming a first layer having a photosensitive response to incident radiation on the substrate, forming a first pattern in the first layer, and exposing the first pattern to ultra-violet radiation. Exposing the first pattern to ultra-violet radiation increases the resistance of the first pattern to a developer. The method also includes forming a conformal protective layer over the first pattern and at least a portion of the substrate and forming a second layer having a photosensitive response to incident radiation over the conformal protective layer. The method further includes forming a second pattern in the second layer.

According to a specific embodiment of the present invention, a track lithography tool for processing a substrate is provided. The track lithography tool includes a plurality of pod assemblies adapted to accept one or more cassettes of substrates and a plurality of processing modules adapted to perform various processing steps associated with the track lithography tool. The plurality of processing modules includes at least one module for coating the substrate with a photoresist material, at least one module for developing the photoresist material, and a curing module configured to expose the photoresist material to ultra-violet radiation. The track lithography tool also includes one or more robots adapted to transfer the substrate from one of the plurality of pod assemblies to one of the plurality of processing modules within the track lithography tool and transfer the substrate among the plurality of processing modules.

According to another specific embodiment of the present invention, a method of performing a double exposure process on a semiconductor substrate is provided. The method includes providing a substrate having an upper surface and a backside surface and forming a first photosensitive layer on the upper surface of the substrate. The method also includes exposing the first photosensitive layer to incident radiation and developing the exposed first photosensitive layer to form a first pattern in the first photosensitive layer. The method further includes exposing the first pattern to ultraviolet radiation characterized by a wavelength of about 172 nm and forming a protective layer covering the first pattern. The protective layer includes silicon. Moreover, the method includes forming a second photoresist layer over the protective layer, exposing the second photosensitive layer to incident radiation, and developing the exposed second photosensitive layer to form a second pattern in the second photosensitive layer.

Many benefits are achieved by way of the present invention over conventional techniques. For example, embodiments of the present invention use a combination of UV cure and a protective layer to freeze a first pattern in a first photosensitive layer. After freezing of the first pattern, formation and patterning of subsequent photosensitive layers can be performed without adversely affecting the first pattern. Another benefit achieved by various embodiments of the present invention is an increase in the resolution of the lithography process. These and other benefits will be described in more detail throughout the present specification and more particularly below in conjunction with the following drawings.

### BRIEF DESCRIPTION OF THE DRAWINGS

FIG. 1 is a simplified schematic diagram of a track lithography tool in which embodiments of the present invention may be implemented;

FIG. 2 is a simplified illustration of an x-grid pattern created by an embodiment of this invention;

FIG. 3 is a simplified illustration of a pitch-split pattern created by an embodiment of this invention;

FIG. 4 is a simplified flowchart illustrating a method of processing a substrate according to an embodiment of the present invention; and

FIGS. 5A-F illustrate a simplified process flow for processing a substrate according to an embodiment of the present invention.

### DETAILED DESCRIPTION OF SPECIFIC EMBODIMENTS

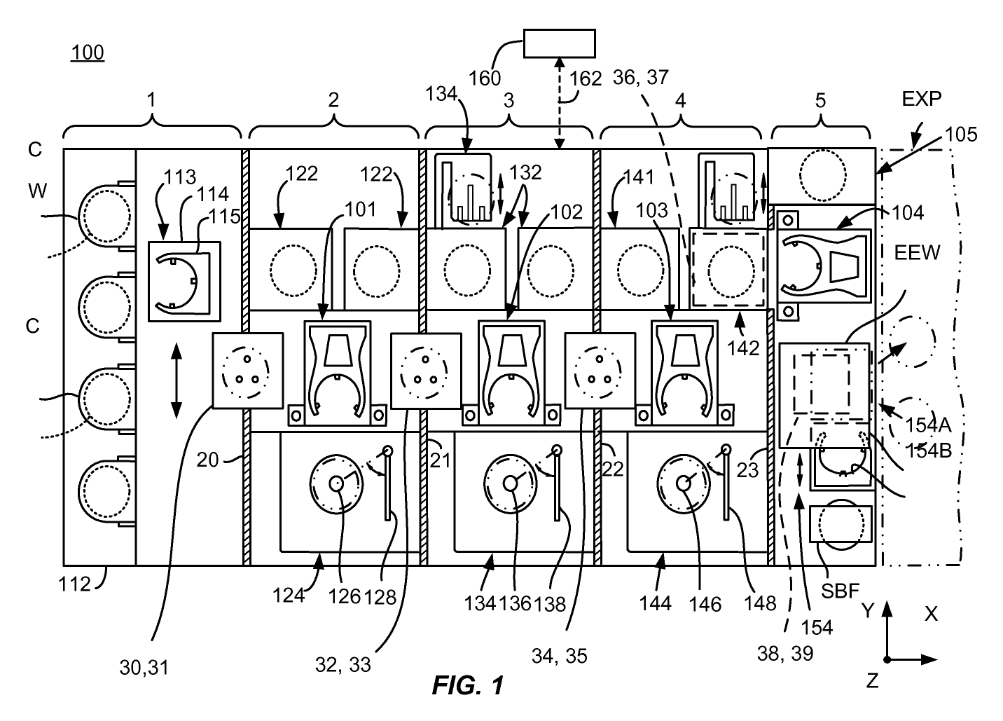

FIG. 1 is a plan view of a track lithography tool according to an embodiment of the present invention. In the embodiment illustrated in FIG. 1, the track lithography tool is coupled to an immersion scanner. An XYZ rectangular coordinate system in which an XY plane is defined as the horizontal plane and a Z-axis is defined to extend in the vertical direction is additionally shown in FIG. 1 for purposes of clarifying the directional relationship therebetween.

In a particular embodiment, the track lithography tool is used to form, through use of a coating process, an anti-reflection (AR) and a photoresist film on substrates, for example, semiconductor substrates. The track lithography tool is also used to perform a development process on the substrates after they have been subjected to a pattern exposure process. The substrates processed by the track lithography tool are not limited to semiconductor substrates, but may include glass substrates for a liquid crystal display device, and the like.

The track lithography tool 100 illustrated in FIG. 1 includes an factory interface block 1, a BARC (Bottom Anti-Reflection Coating) block 2, a resist coating block 3, a development processing block 4, and a scanner interface block 5. In the track lithography tool, the five processing blocks 1 to 5 are arranged in a side-by-side relation. An exposure unit (or stepper) EXP, which is an external apparatus separate from the track lithography tool is provided and coupled to the scanner interface block 5. Additionally, the track lithography tool and the exposure unit EXP are connected via LAN lines 162 to a host computer 160.

The factory interface block 1 is a processing block for transferring unprocessed substrates received from outside of the track lithography tool to the BARC block 2 and the resist coating block 3. The factory interface block 1 is also useful for transporting processed substrates received from the development processing block 4 to the outside of the track lithography tool. The factory interface block 1 includes a table 112 configured to receive a number of (in the illustrated embodiment, four) cassettes (or carriers) C, and a substrate transfer mechanism 113 for retrieving an unprocessed substrate W from each of the cassettes C and for storing a processed substrate W in each of the cassettes C. The substrate transfer mechanism 113 includes a movable base 114, which is movable in the Y direction (horizontally) along the table 112, and a robot arm 115 mounted on the movable base 114.

The robot arm 115 is configured to support a substrate W in a horizontal position during substrate transfer operations. Additionally, the robot arm 115 is capable of moving in the Z direction (vertically) in relation to the movable base 114, pivoting within a horizontal plane, and translating back and forth in the direction of the pivot radius. Thus, using the substrate transfer mechanism 113, the holding arm 115 is able to gain access to each of the cassettes C, retrieve an unprocessed substrate W out of each cassette C, and store a processed substrate W in each cassette C. The cassettes C may be one or several types including: an SMIF (standard mechanical interface) pod; an OC (open cassette), which exposes stored substrates W to the atmosphere; or a FOUP (front opening unified pod), which stores substrates W in an enclosed or sealed space.

The BARC block 2 is positioned adjacent to the factory interface block 1. Partition 20 may be used to provide an atmospheric seal between the factory interface block 1 and the BARC block 2. The partition 20 is provided with a pair of vertically arranged substrate rest parts 30 and 31 each used as a transfer position when transferring a substrate W between the factory interface block 1 and the BARC block 2.

The upper substrate rest part 30 is used for the transport of a substrate W from the factory interface block 1 to the BARC block 2. The substrate rest part 30 includes three support pins. The substrate transfer mechanism 113 of the factory interface block 1 places an unprocessed substrate W, which was taken out of one of the cassettes C, onto the three support pins of the substrate rest part 30. A transport robot 101 in the BARC block 2 (described more fully below) is configured to receive the substrate W placed on the substrate rest part 30. The lower substrate rest part 31, on the other hand, is used for the transport of a substrate W from the BARC block 2 to the factory interface block 1. The substrate rest part 31 also includes three support pins. The transport robot 101 in the BARC block 2 places a processed substrate W onto the three support pins of the substrate rest part 31. The substrate transfer mechanism 113 is configured to receive the substrate W placed on the substrate rest part 31 and then store the substrate W in one of the cassettes C. Pairs of substrate rest parts 32-39 (which are described more fully below) are similar in construction and operate in an analogous manner to the pair of substrate rest parts 30 and 31.

The substrate rest parts 30 and 31 extend through the partition 20. Each of the substrate rest parts 30 and 31 include an optical sensor (not shown) for detecting the presence or absence of a substrate W thereon. Based on a detection signal from each of the sensors, control of the substrate transfer mechanism 113 and the transport robot 101 of the BARC block 2 is exercised to transfer and receive a substrate W to and from the substrate rest parts 30 and 31.

Referring to FIG. 1 again, BARC block 2 is also included in the track lithography tool 100. The BARC block 2 is a processing block for forming an AR film (also referred to as a BARC) on a substrate using a coating process. The BARC is positioned in the film stack under the photoresist film, which is subsequently deposited. The BARC reduces standing waves or halation occurring during exposure. The BARC block 2 includes a bottom coating processor 124 configured to coat the surface of a substrate W with the AR film, a pair of thermal processing towers 122 for performing one or more thermal processes that accompany the formation of the AR film, and the transport robot 101, which is used in transferring and receiving a substrate W to and from the bottom coating processor 124 and the pair of thermal processing towers 122.

In the BARC block 2, the bottom coating processor 124 and the pair of thermal processing towers 122 are arranged on opposite sides of the transport robot 101. Specifically, the bottom coating processor 124 is on the front side of the track lithography tool and the pair of thermal processing towers 122 are on the rear side thereof. Additionally, a thermal barrier (not shown) is provided on the front side of the pair of thermal processing towers 122. Thus, the thermal crosstalk from the pair of thermal processing towers 122 to the bottom coating processor 124 is reduced by the spacing between the bottom coating processor 124 and the pair of thermal processing towers 122 and through the use of the thermal barrier.

Generally, the bottom coating processor 124 includes three vertically stacked coating processing units that are similar in construction. The three coating processing units are collectively referred to as the bottom coating processor 124, unless otherwise identified. Each of the coating processing units includes a spin chuck 126 on which the substrate W is rotated in a substantially horizontal plane while the substrate W is held in a substantially horizontal position through suction. Each coating processing unit also includes a coating nozzle 128 used to apply a coating solution for the AR film onto the substrate W held on the spin chuck 126, a spin motor (not shown) configured to rotatably drive the spin chuck 126, a cup (not shown) surrounding the substrate W held on the spin chuck 22, and the like.

The thermal processing towers 122 include a number of bake plates used to heat a substrate W to a predetermined temperature and a number of cool plates used to cool a heated substrate down to a predetermined temperature and thereafter maintain the substrate at the predetermined temperature. The bake plates and cool plates are vertically stacked, with the cool plates generally mounted underneath the bake plates. The thermal processing towers may also include a number of vertically stacked adhesion promotion units (e.g., HMDS treatment units). Vertical stacking of processing units reduces the tool footprint and reduces the amount of ancillary equipment (e.g., temperature and humidity control apparatus, electrical service, and the like).

Referring once again to FIG. 1, the resist coating block 3 is a processing block for forming a resist film on the substrate W after formation of the AR film in the BARC block 2. In a particular embodiment, a chemically amplified resist is used as the photoresist. The resist coating block 3 includes a resist coating processor 134 used to form the resist film on top of the AR film, a pair of thermal processing towers 132 for performing one or more thermal processes accompanying the resist coating process, and the transport robot 102, which is used to transfer and receive a substrate W to and from the resist coating processor 134 and the pair of thermal processing towers 132.

Similar to the configuration of the processors in BARC block 2, the resist coating processor 134 and the pair of thermal processing towers 132 are arranged on opposite sides of the transport robot 102. A thermal barrier (not shown) is provided to reduce thermal crosstalk between processors. Generally, the resist coating processor 134 includes three vertically stacked coating processing units that are similar in construction. Each of the coating processing units includes a spin chuck 136, a coating nozzle 138 for applying a resist coating to the substrate W, a spin motor (not shown), a cup (not shown), and the like.

The thermal processing towers 132 include a number of vertically stacked bake chambers and cool plates. In a particular embodiment, the thermal processing tower closest to the factory interface block 1 includes bake chambers and the thermal processing tower farthest from the factory interface block 1 includes cool plates. In the embodiment illustrated in FIG. 1, the bake chambers include a vertically stacked bake plate and temporary substrate holder as well as a local transport mechanism 134 configured to move vertically and horizontally to transport a substrate W between the bake plate and the temporary substrate holder and may include an actively chilled transport arm. The transport robot 102 is identical in construction to the transport robot 101 in some embodiments. The transport robot 102 is able to independently access substrate rest parts 32 and 33, the thermal processing towers 132, the coating processing units provided in the resist coating processor 134, and the substrate rest parts 34 and 35.

The development processing block 4 is positioned between the resist coating block 3 and the scanner interface block 5. A partition 22 for sealing the development processing block from the atmosphere of the resist coating block 3 is provided. The upper substrate rest part 34 is used to transport a substrate W from the resist coating block 3 to the development processing block 4. The lower substrate rest part 35, on the other hand, is used to transport a substrate W from the development processing block 4 to the resist coating block 3. As described above, substrate rest parts 32-39 may include an optical sensor for detecting the presence or absence of a substrate W thereon. Based on a detection signal from each of the sensors, control of the various substrate transfer mechanisms and transport robots of the various processing blocks is exercised during substrate transfer processes.

The development processing block 4 includes a development processor 144 for applying a developing solution to a substrate W after exposure in the scanner EXP, a pair of thermal processing towers 141 and 142, and transport robot 103. The development processor 144 includes five vertically stacked development processing units that are similar in construction to each other. Each of the development processing units includes a spin chuck 146, a nozzle 148 for applying developer to a substrate W, a spin motor (not shown), a cup (not shown), and the like.

Thermal processing tower 142 includes bake chambers and cool plates as described above. Additionally, thermal processing tower 142 is accessible to both transport robot 103 as well as transport robot 104. Thermal processing unit 141 is accessible to transport robot 103. Additionally, thermal processing tower 142 includes substrate rest parts 36 and 37, which are used when transferring substrates to and from the development processing block 4 and the scanner interface block 5.

The interface block 5 is used to transfer a coated substrate W to the scanner EXP and to transfer an exposed substrate to the development processing block 5. The interface block 5 in this illustrated embodiment includes a transport mechanism 154 for transferring and receiving a substrate W to and from the exposure unit EXP, a pair of edge exposure units EEW for exposing the periphery of a coated substrate, a curing module 105 and transport robot 104. The curing module 105 can be configured to expose the wafer to incident radiation and is separate from the exposure module EXP described below. Typically, the curing module is configured to allow the substrate to be exposed to ultra-violet radiation, but can also be configured with other types of radiation sources. Substrate rest parts 38 and 39 are provided along with the pair of edge exposure units EEW for transferring substrates to and from the scanner and the development processing unit 4.

The exposure unit EXP is configured to allow the substrate to be exposed to incident radiation of various wavelengths. The exposure unit EXP usually consists of an illumination source that generates the radiation. The typical illumination sources used in an exposure unit are gas discharge lamps using either Krypton Fluoride (KrF), Argon Fluoride (ArF), or other suitable lamps. These particular lamps generate radiation with wavelengths of 248 nm and 193 nm, respectively.

The transport mechanism 154 includes a movable base 154A and a holding arm 154B mounted on the movable base 154A. The holding arm 154B is capable of moving vertically, pivoting, and moving back and forth in the direction of the pivot radius relative to the movable base 154A. The send buffer SBF is provided to temporarily store a substrate W prior to the exposure process if the exposure unit EXP is unable to accept the substrate W, and includes a cabinet capable of storing a plurality of substrates W in tiers.

Controller 160 is used to control all of the components and processes performed in the cluster tool. The controller 160 is generally adapted to communicate with the scanner EXP, monitor and control aspects of the processes performed in the cluster tool, and is adapted to control all aspects of the complete substrate processing sequence. The controller 160, which is typically a microprocessor-based controller, is configured to receive inputs from a user and/or various sensors in one of the processing chambers and appropriately control the processing chamber components in accordance with the various inputs and software instructions retained in the controller's memory. The controller 160 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 160 determines which tasks are performable in the processing chambers. Preferably, the program is software readable by the controller 160 and includes instructions to monitor and control the process based on defined rules and input data.

Although embodiments of the present invention are described herein in the context of the track lithography tool illustrated in FIG. 1, other architectures for track lithography tools are included within the scope of embodiments of the present invention. For example, track lithography tools utilizing Cartesian architectures are suitable for use with embodiments as described throughout the present specification. In a particular embodiment, implementation is performed for an RF³i, available from Sokudo Co., Ltd. of Kyoto, Japan.

The challenges to high-resolution lithography are encapsulated in the resolution equation: CD=k1*I/NA, where CD is the smallest attainable critical dimension, k1 is a measure of process difficulty, I is the illumination wavelength, and NA is the effective numerical aperture of the optical system. Some resolution enhancement techniques involve methods that reduce k1 at a given I and NA and therefore reduce the minimum CD. According to ITRS, the k1 needs to be reduced to less than 0.3 for the 45 nm node and beyond to enable the continued use of the existing lithography equipment. Moreover, very tight CD control is essential as the industry moves towards smaller feature sizes.

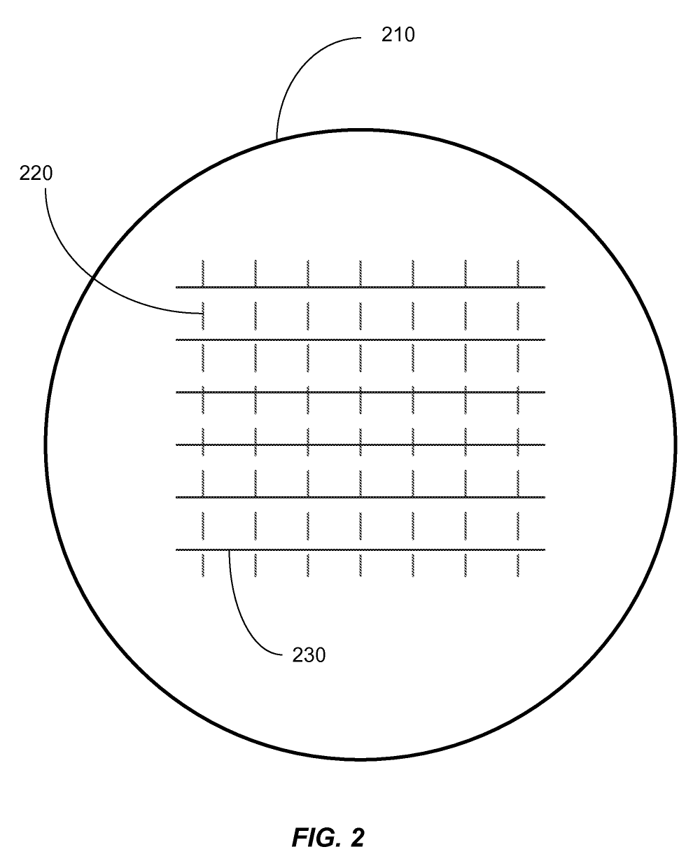

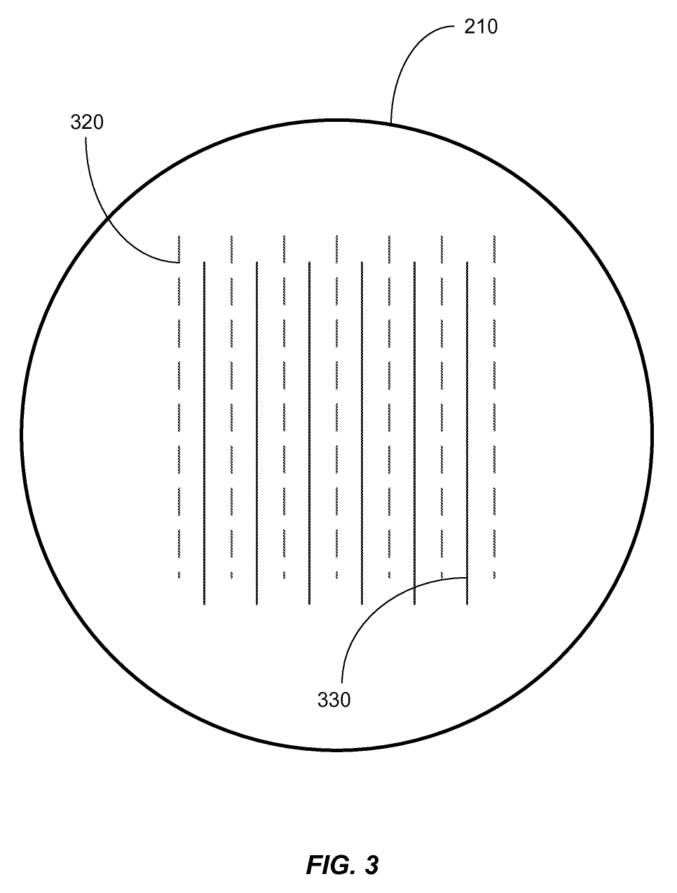

FIG. 2 and FIG. 3 illustrate test patterns created by a lithographic process employing embodiments of the present invention. These are typical patterns used to test the viability of a particular lithography process. The patterns are formed on a substrate 210, typically a silicon wafer, however, other suitable substrates including GaAs substrates, GaN substrates, glass substrates for LCD applications, or the like, are included within the scope of embodiments of the present invention. In FIG. 2, a first test pattern 220 (illustrated with dashed lines) is formed and then a second test pattern 230 is formed that is perpendicular to the first pattern 220. This pattern type is generally referred to as an “x-grid” pattern.

FIG. 3 shows another pattern where two patterns 320 (illustrated with dashed lines) and 330 are interposed between each other. The resulting pattern is commonly referred to as “pitch-split” pattern. The patterns described herein are for purposes of illustration only and one skilled in the art will recognize that numerous other patterns can be used to test a particular lithography process. Further, one skilled in the art will appreciate that the pattern formed by the lithography process during actual manufacturing of a device is likely to be far more complicated than the test patterns described above.

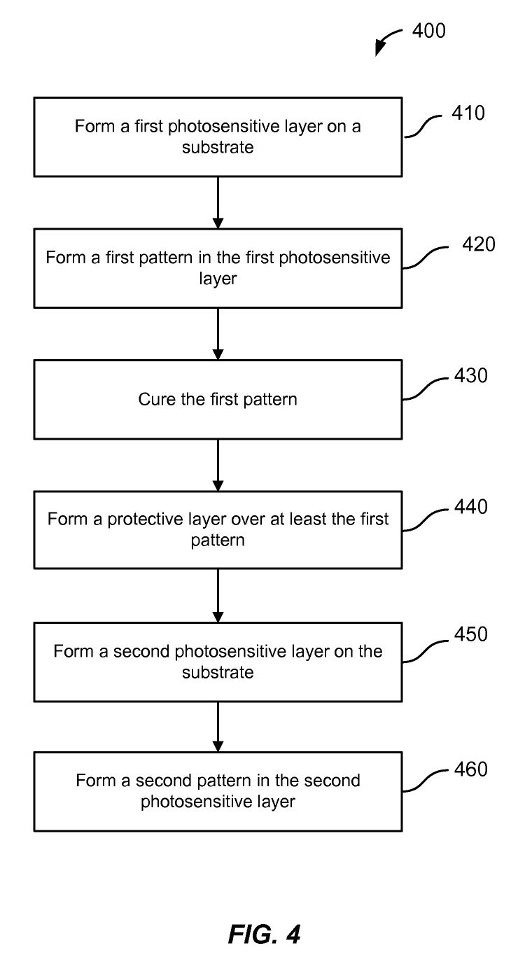

FIG. 4 is a simplified flowchart illustrating a method of processing a substrate according to an embodiment of the present invention. The method 400 is performed using a substrate having an upper surface and a backside surface. A first layer that has a photosensitive response to incident radiation is formed on the upper surface of the substrate (410). The first layer can be formed using any of the commonly known methods in the industry, for example a spin-on technique. Generally, the first layer is formed using chemically amplified photoresist although embodiments of the present invention are not limited to such resists. Other suitable materials that are characterized by a photosensitive response to incident radiation are included within the scope of the present invention. Additionally, the incident radiation is generally UV radiation associated with a scanner or other semiconductor lithographic exposure tools. Pre-exposure baking/chilling of the substrate having the first layer and other processing steps are not discussed herein for purposes of clarity. One of ordinary skill in the art would recognize many variations, modifications, and alternatives.

After the first layer is formed, a mask having transmissive sections defining a predetermined pattern is positioned over the substrate in a desired location. The mask may be mechanically supported in a mask aligner associated with the scanner. The substrate is then exposed to radiation from the scanner or other suitable radiation source. The mask allows the radiation to only pass through the transmissive sections, thereby exposing a pattern (420) in the first layer. The first layer is then developed using commonly known developing techniques to reveal the pattern exposed in the first layer formed on the upper surface of the substrate. In FIG. 4, the method of forming the first pattern in the first photosensitive layer (420) includes the aforementioned processes and other appropriate processes (e.g., post-exposure bake) that are not described in detail for purposes of clarity.

The first pattern thus formed is then cured by exposing it to ultraviolet radiation in (430). Various wavelengths of ultra-violet radiation can be used in the process of curing the first pattern, including wavelengths ranging over a predetermined range. In one embodiment, the wavelength of the ultra-violet radiation utilized to cure the first pattern is 172 nm. The curing dosage of the ultra-violet radiation will depend on the type of resist used, among other factors. In one embodiment, the curing dosage ranges from about 400 mJ/cm² to about 2000 mJ/cm². The duration of the curing step depends on the type of photosensitive material present in the first layer and is generally in the range of 50 seconds to about 200 seconds. In a particular embodiment, the curing process is carried out for about 180 seconds. As a result of the curing process, the first pattern becomes resistant to a developer that is used in conjunction with formation of a second pattern described more fully throughout the present specification and more particularly below.

Following the curing process, a protective layer is deposited over at least the first pattern and the substrate (440). In one embodiment, the protective layer includes a silicon material (e.g., polysilicon). In alternative embodiments, the protective layer could include one or more additional materials, for example, amorphous carbon, titanium, silicon nitride, silicon oxide, combinations thereof, and the like.

The protective layer has the characteristic of being resistant to dissolution in photosensitive materials (e.g., photoresist) and protects the first pattern during subsequent photosensitive layer formation processes. The protective layer can be formed using any of several semiconductor deposition processes like chemical vapor deposition (CVD), physical vapor deposition (PVD), spin-on processes, atomic layer deposition (ALD), or the like. In a particular embodiment, the protective layer is formed as a conformal layer using an ALD process that forms a predetermined number of atomic monolayers of material. The temperature at which the deposition of the protective layer is carried out will depend on the type of deposition process used. The general range of the temperature at which the deposition of the protective layer is carried out ranges from about 80° C. to about 120° C. In a specific embodiment, the protective layer is deposited at a temperature of about 90° C.

The thickness of the protective layer formed over the first pattern is selected in order to provide sufficient thickness such that the first pattern is resistant to dissolution during subsequent processing steps. At the same time, the thickness of the protective layer is selected to be thin enough to not significantly impede subsequent processing. Typically, the protective layer is between 20 Å to 50 Å thick. In one embodiment the protective layer is about 30 Å thick. Utilizing ALD processes, a silicon-bearing layer of these thicknesses is provided in a specific embodiment.

Next, a second layer having a photosensitive response to incident radiation is formed over the protective layer (450). As mentioned above, several techniques can be employed to form this second photosensitive layer. Generally, the second layer is formed using photoresist, for example, the same chemically amplified photoresist utilized to form the first layer or a different photoresist. A second pattern is formed in the second layer (460). The second pattern is subsequently developed using similar techniques as described above in reference to the first pattern. The protective layer is then removed to reveal the first and second pattern on the upper surface of the substrate.

In an alternate embodiment, prior to forming the second photosensitive layer, the substrate having the first pattern and the protective layer is treated with hexamethyldisilazane (HMDS) or other suitable adhesion promoter(s). This process step improves the adhesion of the second photosensitive layer to the protective layer. The time for the HMDS treatment varies according to the particular application and is generally is the range of 20 seconds to 50 seconds. In a specific embodiment, the HMDS treatment is carried out for about 30 seconds. One of ordinary skill in the art would recognize many variations, modifications, and alternatives.

It should be appreciated that the specific steps illustrated in FIG. 4 provide a particular method of processing a substrate according to an embodiment of the present invention. Other sequences of steps (for example, pre-exposure bake, post-exposure bake, and the like) may also be performed according to alternative embodiments. For example, alternative embodiments of the present invention may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular applications. One of ordinary skill in the art would recognize many variations, modifications, and alternatives.

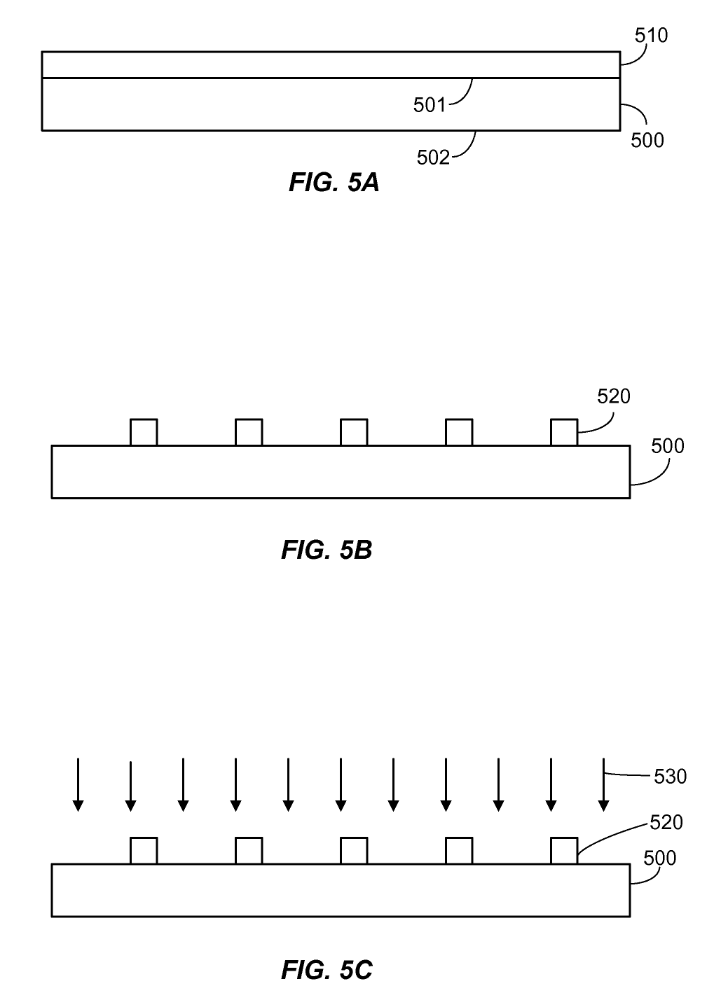

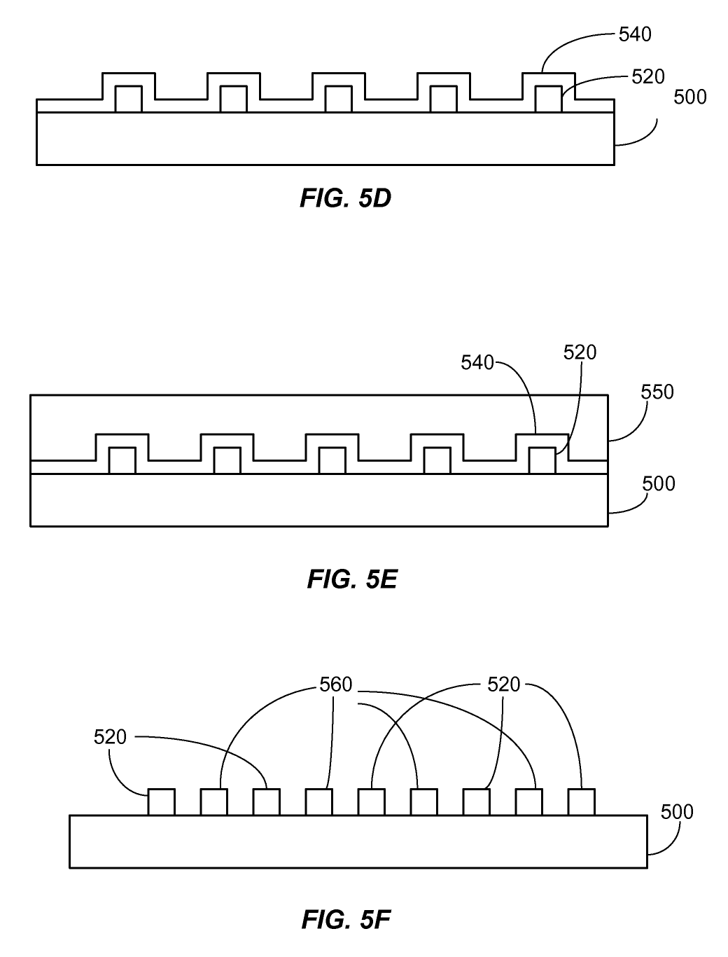

FIGS. 5A-F illustrate a simplified process flow for processing a substrate according to an embodiment of the present invention. The process flow utilizes a substrate 500 having an upper surface 501 and a backside surface 502. A first layer 510 that has a photosensitive response to incident radiation is formed on the upper surface 501 of the substrate 500. The first layer 510 is formed using one of several techniques, such as a spin-on technique. The first layer 510 is typically formed using photoresist. In other embodiments, the thickness of the first layer varies as appropriate to the particular application. Adhesion promoters, BARC layers, and the like (not illustrated for purposes of clarity) may be formed in conjunction with the first layer 510. One of ordinary skill in the art would recognize many variations, modifications, and alternatives.

After the formation of the first layer 510, a mask (not shown) having transmissive sections defining a predetermined pattern is positioned over the first layer 510 in a desired location. The substrate is then exposed to radiation passing through the mask to thereby expose a portion of the first layer. Since the mask allows the radiation to only pass through the transmissive sections, a pattern is exposed in the first layer 510. The substrate/mask combination may be exposed in a scanner coupled to a track lithography tool or in a separate module provided in the track lithography tool. Utilizing a module provided in the track lithography tool, wavelengths not available from the scanner may be used, thereby supplementing the exposure wavelengths provided by the scanner. The first layer is then developed using developing techniques to reveal the pattern 520 on the upper surface of the substrate 500 as illustrated in FIG. 5B.

The first pattern 520 thus formed is then cured by exposing it to ultraviolet radiation as illustrated in FIG. 5C. As discussed above, the wavelength of ultra-violet radiation utilized to cure the first pattern 520, the dosage, and the exposure time can vary depending on the source (scanner or separate module), the type of material utilized to fabricate the first layer, and the like. In an exemplary embodiment, the wavelength of the ultra-violet radiation is 172 nm, the curing dosage is a predetermined curing dosage, and the exposure time is 180 seconds. As a result of the curing process, the first pattern 520 becomes resistant to dissolution during a development process that is used in conjunction with a second pattern described in relation to FIG. 5F.

Following the curing process illustrated in FIG. 5C, a protective layer 540 is formed over at least the first pattern 520 and the substrate 500. The formation of the protective layer 540 is illustrated in FIG. 5D. In a particular embodiment, the protective layer is a 30 Å thick polysilicon layer formed using an ALD process at 90° C. that protects the first pattern from dissolution by photoresist in subsequent processing steps. Thus, as illustrated in FIG. 5E, a conformal protective layer is formed in some embodiments. In alternative embodiments, the protective layer could include one or more materials such as amorphous carbon, titanium, silicon nitride, silicon oxide, combinations thereof, and the like. One of ordinary skill in the art would recognize many variations, modifications, and alternatives.

A second layer 550 having a photosensitive response to incident radiation (e.g., a photoresist layer) is formed over the protective layer 540 as also illustrated in FIG. 5E. Generally, the thickness of the second layer 550 ranges from over a predetermined range. As mentioned above, one or more techniques are utilized to form the second layer 550. Referring to FIG. 5F, a second pattern 560 is formed and subsequently developed in the second layer 550. Although not illustrated, the formation of the second pattern 560 entails several processing steps such as baking/chilling, masking, exposure, post-exposure baking, and the like. The protective layer 540 is then removed to reveal the first pattern 520 and the second pattern 560 on the upper surface of the substrate 500. Additionally, although not illustrated in FIG. 5F, the second pattern 560 is actually formed over portions of the protective layer. In some embodiments, the thickness of the protective layer, which may be in the tens of angstroms, is small in comparison to the thickness of the second layer, which may be a chemically amplified photoresist. One of ordinary skill in the art would recognize many variations, modifications, and alternatives.

According to embodiments of the present invention, the protective layer 540 prevents the first pattern 520 from being dissolved during the formation and patterning of the second layer 550. The curing of the first pattern as illustrated in FIG. 5C, causes the first pattern to be resistant to the developer process that is used to develop the second pattern 560 as illustrated in FIG. 5F. Thus, the combination of the curing process and the protective layer protect the first pattern from both photoresist layer formation and development processes utilized to form the second pattern.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A method of processing a substrate, the method comprising:
forming a first layer having a photosensitive response to incident radiation on the substrate;
forming a first pattern in the first layer;
exposing the first pattern to ultra-violet radiation, thereby increasing the resistance of the first pattern to a developer;
forming a conformal protective layer over the first pattern and at least a portion of the substrate;
forming a second layer having a photosensitive response to incident radiation over the conformal protective layer; and
forming a second pattern in the second layer.

2. The method of claim 1 wherein the first layer and the second layer comprise a photoresist material.

3. The method of claim 1 wherein forming a first pattern comprises:
positioning a mask over the substrate, the mask having one or more transmissive sections associated the first pattern;
exposing the first layer to the ultra-violet radiation through the mask; and
developing the first layer to form the first pattern.

4. The method of claim 1 wherein the ultra-violet radiation is characterized by a wavelength of about 172 nm.

5. The method of claim 1 wherein the ultra-violet radiation is characterized by a dosage ranging from 400 to 2000 mJ/cm².

6. The method of claim 1 wherein forming the conformal protective layer comprises depositing the protective layer using at least an atomic layer deposition process.

7. The method of claim 6 wherein the atomic layer deposition process is characterized by a process temperature ranging from about 80° C. to about 120° C.

8. The method of claim 7 wherein the process temperature is about 90° C.

9. The method of claim 1 wherein the conformal protective layer comprises silicon.

10. The method of claim 1 wherein the conformal protective layer is characterized by a thickness ranging from about 20 Å to about 50 Å.

11. The method of claim 10 wherein the thickness is about 30 Å.

12. A track lithography tool for processing a substrate, the track lithography tool comprising:
a plurality of pod assemblies adapted to accept one or more cassettes of substrates;
a plurality of processing modules adapted to perform various processing steps associated with the track lithography tool, the plurality of processing modules including:
at least one module for coating the substrate with a photoresist material,
at least one module for developing the photoresist material, and
a curing module configured to expose the photoresist material to ultra-violet radiation; and
one or more robots adapted to transfer the substrate from one of the plurality of pod assemblies to one of the plurality of processing modules within the track lithography tool and transfer the substrate among the plurality of processing modules.

13. The track lithography tool of claim 12 wherein the ultra-violet radiation is characterized by a wavelength of about 172 nm.

14. A method of performing a double exposure process on a semiconductor substrate, the method comprising:
providing a substrate having an upper surface and a backside surface;
forming a first photosensitive layer on the upper surface of the substrate;
exposing the first photosensitive layer to incident radiation;
developing the exposed first photosensitive layer to form a first pattern in the first photosensitive layer;
exposing the first pattern to ultraviolet radiation characterized by a wavelength of about 172 nm;
forming a protective layer covering the first pattern, wherein the protective layer comprises silicon;
forming a second photoresist layer over the protective layer;
exposing the second photosensitive layer to incident radiation; and
developing the exposed second photosensitive layer to form a second pattern in the second photosensitive layer.

15. The method of claim 14 wherein the ultra-violet radiation is characterized by a dosage ranging from 400 to 2000 mJ/cm².

16. The method of claim 14 wherein forming the protective layer comprises performing an atomic layer deposition process.

17. The method of claim 16 wherein the protective layer is a conformal layer.

18. The method of claim 14 further comprising treating the protective layer with HMDS prior to forming the second photosensitive layer over the protective layer.

19. The method of claim 18 wherein treating the protective layer with HMDS is performed for a period of about 30 seconds.

20. The method of claim 14 wherein exposing the first pattern to ultra-violet radiation is performed for a period of about 180 seconds in a scanner coupled to a track lithography tool.
